(19) United States
(12) Patent Application Publication
(10) Pub. No.: US 2025/0138062 A1
(43) Pub. Date: May 1, 2025

(54) HIGH-END VOLTAGE DIFFERENTIAL SAMPLING AND CALIBRATION SYSTEM AND METHOD

(71) Applicant: MACROTEST SEMICONDUCTOR TECHNOLOGY CO., LTD, Nanjing (CN)

(72) Inventors: Xing ZHONG, Nanjing (CN); Zhijie BAO, Nanjing (CN)

(21) Appl. No.: 18/262,384

(22) PCT Filed: Mar. 15, 2023
(86) PCT No.: PCT/CN2023/081501

§ 371 Date: Jul. 21, 2023

(30) Foreign Application Priority Data
Jul. 12, 2022 (CN) 202210813322.2

(51) Int. Cl. G01R 19/25; G01R 19/10; G01R 35/00

(52) U.S. Cl. CPC G01R 19/2509; G01R 19/10; G01R 35/005

(57) ABSTRACT

The present disclosure discloses a high-end voltage differential sampling and calibration system and method. The system includes an accuracy detector, a calibration controller, a differential operational amplifier, a comparator, a memory, and a digital to analog converter (DAC). An output characteristic is converted through the DAC U1 to achieve conversion of an acquired voltage signal value, thus achieving a high-accuracy output voltage difference. The high-accuracy detector and the high-precision calibration controller are used to be compared with an output voltage of the differential operational amplifier, and a difference value is calibrated and compensated to an output end to achieve a stable state of the output voltage. The present disclosure improves the stability and accuracy of voltage outputting, and has high measurement accuracy, high effect, and excellent stability.

### TECHNICAL FIELD

The present disclosure relates to a high-end voltage differential sampling and calibration system and method, and belongs to the technical field of voltage detection.

### BACKGROUND

There is a deviation in voltage output accuracy in the prior art, and an ideal state cannot be achieved when a stable output is required. If a desired voltage in a circuit needs to achieve an accurate value, a tested voltage cannot achieve a desired and intuitional accuracy effect through various devices. In a testing process, the voltage changes frequently and has relatively poor stability. Therefore, a value obtained by sampling a voltage signal is not accurate in the prior art, and an output voltage fluctuation is unstable. In an actual test of a voltage output, due to an excessive voltage bias, test data loss may occur, resulting in inaccurate measured data and a failure of test results. In the testing process, results of test items are at edges of numerical ranges, and finding specific causes of faults is time-consuming and laborious.

### SUMMARY

Objective of the present disclosure: In order to overcome the shortcomings in the prior art, the present disclosure provides a high-end voltage differential sampling and calibration system and method.

Technical solution: in order to achieve the above purpose, the present disclosure adopts the technical solution below.

A high-end voltage differential sampling and calibration system includes an accuracy detector, a calibration controller, a differential operational amplifier, a comparator, a memory, and a digital to analog converter (DAC),
wherein the differential operational amplifier is configured to: acquire a non-inverting voltage and an inverting voltage of a to-be-tested device, and output the non-inverting voltage and the inverting voltage to the comparator;
the comparator is configured to: acquire the non-inverting voltage and the inverting voltage which are output by the differential operational amplifier, and output the acquired non-inverting voltage and inverting voltage to the memory;
the accuracy detector is configured to: detect a difference value between the non-inverting voltage and the inverting voltage of the to-be-tested device acquired by the differential operational amplifier, and send the detected difference value to the calibration controller;
the calibration controller compensates, according to the difference value sent by the accuracy detector, the non-inverting voltage and the inverting voltage which are stored in the memory to obtain a non-inverting voltage for compensation and an inverting voltage for compensation; and
the DAC is configured to: perform signal conversion on the non-inverting voltage for compensation and the inverting voltage for compensation which are obtained by the calibration controller, and compensate a converted signal to an output voltage of the differential operational amplifier.

Preferably, the sampling and calibration system includes an operational amplifier II U2, a resistor I R1, a resistor II R2, a DAC U1, a capacitor II C2, an operational amplifier III U3, a resistor X R10, a network resistor II RN2, an operational amplifier VI U6, a capacitor III C3, an operational amplifier V U5, a network resistor I RN1, a resistor LX R9, a resistor VI R6, a resistor VII R7, a resistor V R5, a resistor IV R4, and an operational amplifier IV U4, wherein:
an inverting input terminal of the operational amplifier II U2 is connected to a power input terminal I IN1; a non-inverting input terminal of the operational amplifier II U2 is grounded; an output end of the operational amplifier II U2 is connected to a reference signal input terminal of the DAC U1;
an inverting input terminal of the operational amplifier III U3 is connected to a signal output terminal I of the DAC U1; a non-inverting input terminal of the operational amplifier III U3 is connected to a signal output terminal II of the DAC U1; the non-inverting input terminal of the operational amplifier III U3 is grounded; an output end of the operational amplifier III U3 is connected to a feedback signal terminal Rfb of the DAC U1; one end of the capacitor II C2 is connected to the feedback signal terminal Rfb of the DAC U1, and the other end is connected to the signal output terminal of the DAC U1;
an inverting input terminal of the operational amplifier VI U6 is connected to the output end of the operational amplifier III U3 through the resistor X R10; a non-inverting input terminal of the operational amplifier VI U6 is grounded; an output end of the operational amplifier VI U6 is connected to an output end II Force; one end of the capacitor C2 is connected to the inverting input terminal of the operational amplifier VI U6, and the other end is connected to the output end of the operational amplifier VI U6; a test point II TP2 is arranged on a connecting line between the output end II Force and the output end of the operational amplifier VI U6; the test point II TP2 is connected with the inverting input terminal of the operational amplifier VI U6 through the network resistor II RN2;
an inverting input terminal of the operational amplifier V U5 is connected to a power input terminal I IN1 through the network resistor I RN1; a non-inverting input terminal of the operational amplifier V U5 is grounded; an output end of the operational amplifier V U5 is connected to the inverting input terminal of the operational amplifier VI U6 through the resistor LY R9 and the network resistor II RN2; the inverting input terminal of the operational amplifier V U5 is connected to the output end of the operational amplifier V U5 through the network resistor I RN1;
an inverting input terminal of the operational amplifier IV U4 is connected to a test point I TP1; a non-inverting input terminal of the operational amplifier IV U4 is connected to a power input terminal II IN2 through the resistor IV R4; an output end of the operational amplifier IV U4 is connected to the test point I TP1 through the resistor V R5; the test point I TP1 is connected to the non-inverting input terminal of the operational amplifier V U5 through the network VI R6 and the network resistor I RN1; and the resistor VII R7 is connected in parallel at both ends of the resistor VI R6; and
a sampling resistor RF is connected between the power input terminal II IN2 and the power input terminal I IN1.

A high-end voltage differential sampling and calibration method includes the following steps:
step 1, the power input terminal I IN1 provides an inverting voltage source, and the power input terminal II IN2 provides a non-inverting voltage source;
step 2, the sampling resistor RF is used as a point for sampling a voltage at two ends and acquiring a voltage value; and
step 3, when an inverting voltage needs to be acquired, the inverting voltage flows through the network resistor I RN1 to the inverting input terminal of the operational amplifier V U5, is output to the resistor LX R9, the network resistor II RN2, the operational amplifier VI U6, and the output end II Force in sequence through the output end of the operational amplifier V U5, and flows out of an output port through the output end II Force; at this time, a voltage at the output port of the output end II Force is not within a test range, tested data of the accuracy detector and tested data of the calibration controller need to be compared to obtain a difference value, and then the obtained difference value is transmitted to the memory; the calibration controller compensates the non-inverting and inverting voltages stored in the memory according to the difference value obtained by the accuracy detector to obtain a non-inverting voltage for compensation and an inverting voltage for compensation; and the DAC U1 performs signal conversion on the non-inverting voltage for compensation and the inverting voltage for compensation, and compensates a converted signal to an output voltage of the differential operational amplifier.

Compared with the prior art, the present disclosure has the following beneficial effects:

According to the characteristic of the DAC U1 for converting an output, the present disclosure achieves conversion of an acquired voltage signal value, thus achieving a high-accuracy output voltage difference. The high-accuracy detector and the high-precision calibration controller are used to be compared with an output voltage of the differential operational amplifier, and a difference value is calibrated and compensated to an output end to achieve a stable state of the output voltage. The present disclosure improves the stability and accuracy of voltage outputting, and has high measurement accuracy, high effect, and excellent stability.

### BRIEF DESCRIPTION OF THE DRAWINGS

FIG. 1 is a schematic structural diagram of the present disclosure.

FIG. 2 is a circuit diagram of the present disclosure.

### DETAILED DESCRIPTION OF THE EMBODIMENTS

The present disclosure will be further clarified below in combination with the accompanying drawings and specific embodiments. It should be understood that these examples are only used to illustrate the present disclosure and not to limit the scope of the present disclosure. Modifications made by those skilled in the art in various forms of valence all fall within the scope defined by the appended claims of the present application.

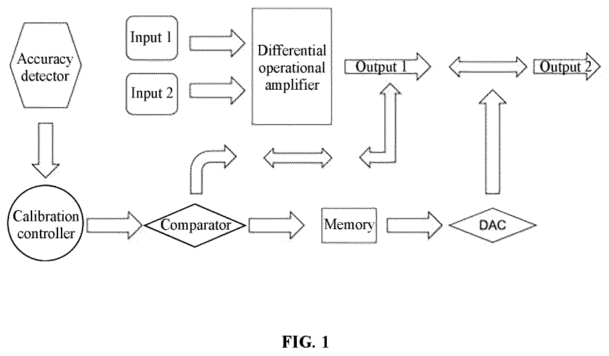

A high-end voltage differential sampling and calibration system, as shown in FIG. 1, includes an accuracy detector, a calibration controller, a differential operational amplifier, a comparator, a memory, and a DAC,
wherein the differential operational amplifier is configured to: acquire a non-inverting voltage and an inverting voltage of a to-be-tested device, and output the non-inverting voltage and the inverting voltage to the comparator;
the comparator is configured to: acquire the non-inverting voltage and the inverting voltage which are output by the differential operational amplifier, and output the acquired non-inverting voltage and inverting voltage to the memory;
the accuracy detector is configured to: detect a difference value between the non-inverting voltage and the inverting voltage of the to-be-tested device acquired by the differential operational amplifier, and send the detected difference value to the calibration controller;
the calibration controller compensates, according to the difference value sent by the accuracy detector, the non-inverting voltage and the inverting voltage which are stored in the memory to obtain a non-inverting voltage for compensation and an inverting voltage for compensation; and
the DAC is configured to: perform signal conversion on the non-inverting voltage for compensation and the inverting voltage for compensation which are obtained by the calibration controller, and compensate a converted signal to an output voltage of the differential operational amplifier.

As calibration tools, the accuracy detector and the calibration controller are compared with voltage values at an output I end and an output II end of the differential operational amplifier, and data signals are stored in the memory. When an output I is a non-ideal state of an output voltage, an output II is a compensation voltage difference value after comparison with a value detected by the accuracy detector, and a difference value of an ideal voltage value is compensated to the output II end through the DAC to achieve a high-accuracy state of the voltage at the output end. The tools provided include the accuracy detector and the calibration controller. Devices provided by a circuit include the differential operational amplifier, the comparator, the memory, and a DAC chip. An input I and an input II are a non-inverting input voltage and an inverting input voltage of the operational amplifier; the output I is a voltage at the output end of the operational amplifier; and the output II is a compensated voltage. When a voltage within an accurate range needs to be output, sampling is performed by using the comparator, and data is transmitted to the memory. After the difference value for compensation is obtained by using the accuracy detector and the calibration controller, the output voltage value is converted through the DAC and is then added to or subtracted from the voltage at the output end to obtain an ideal output voltage state.

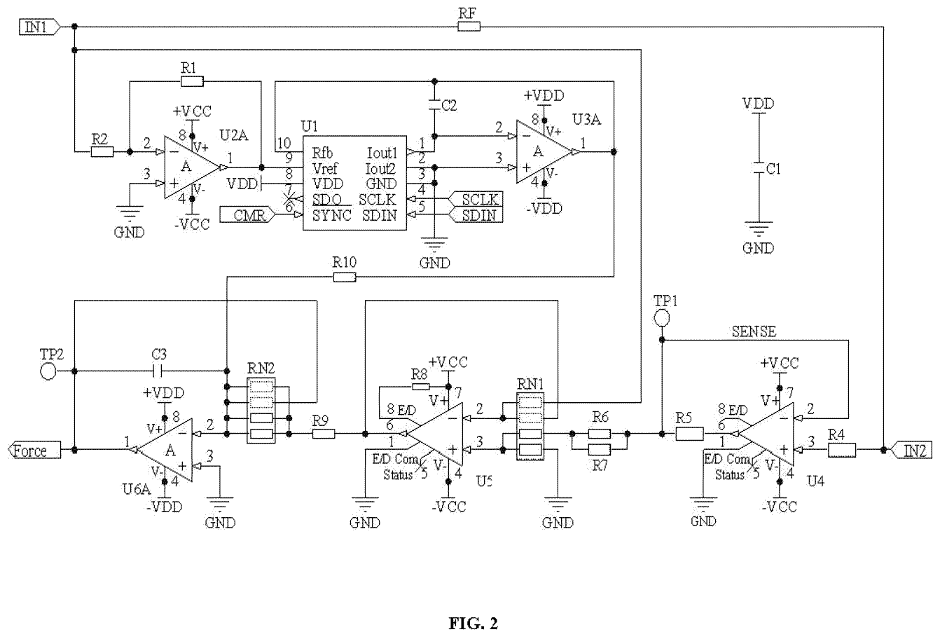

As shown in FIG. 2, the sampling and calibration system includes an operational amplifier II U2, a resistor I R1, a resistor II R2, a DAC U1, a capacitor II C2, an operational amplifier III U3, a resistor X R10, a network resistor II RN2, an operational amplifier VI U6, a capacitor III C3, an operational amplifier V U5, a network resistor I RN1, a resistor LY R9, a resistor VI R6, a resistor VII R7, a resistor V R5, a resistor IV R4, and an operational amplifier IV U4, wherein:
an inverting input terminal of the operational amplifier II U2 is connected to a power input terminal I IN1; a non-inverting input terminal of the operational amplifier II U2 is grounded; an output end of the operational amplifier II U2 is connected to a reference signal input terminal of the DAC U1;
an inverting input terminal of the operational amplifier III U3 is connected to a signal output terminal I of the DAC U1; a non-inverting input terminal of the operational amplifier III U3 is connected to a signal output terminal II of the DAC U1; the non-inverting input terminal of the operational amplifier III U3 is grounded; an output end of the operational amplifier III U3 is connected to a feedback signal terminal Rfb of the DAC U1; one end of the capacitor II C2 is connected to the feedback signal terminal Rfb of the DAC U1, and the other end is connected to the signal output terminal of the DAC U1;
an inverting input terminal of the operational amplifier VI U6 is connected to the output end of the operational amplifier III U3 through the resistor X R10; a non-inverting input terminal of the operational amplifier VI U6 is grounded; an output end of the operational amplifier VI U6 is connected to an output end II Force; one end of the capacitor C2 is connected to the inverting input terminal of the operational amplifier VI U6, and the other end is connected to the output end of the operational amplifier VI U6; a test point II TP2 is arranged on a connecting line between the output end II Force and the output end of the operational amplifier VI U6; the test point II TP2 is connected with the inverting input terminal of the operational amplifier VI U6 through the network resistor II RN2;
an inverting input terminal of the operational amplifier V U5 is connected to a power input terminal I IN1 through the network resistor I RN1; a non-inverting input terminal of the operational amplifier V U5 is grounded; an output end of the operational amplifier V U5 is connected to the inverting input terminal of the operational amplifier VI U6 through the resistor LX R9 and the network resistor II RN2; the inverting input terminal of the operational amplifier V U5 is connected to the output end of the operational amplifier V U5 through the network resistor I RN1;
an inverting input terminal of the operational amplifier IV U4 is connected to a test point I TP1; a non-inverting input terminal of the operational amplifier IV U4 is connected to a power input terminal II IN2 through the resistor IV R4; an output end of the operational amplifier IV U4 is connected to the test point I TP1 through the resistor V R5; the test point I TP1 is connected to the non-inverting input terminal of the operational amplifier V U5 through the network VI R6 and the network resistor I RN1; and the resistor VII R7 is connected in parallel at both ends of the resistor VI R6; and
a sampling resistor RF is connected between the power input terminal II IN2 and the power input terminal I IN1.

The power input terminal IN provides a voltage value at two ends of the sampling resistor RF. The power input terminal II IN2 isolates a non-inverting input of the operational amplifier through the operational amplifier IV U4 to make an input equal to an output. One voltage is connected to the non-inverting input terminal of the operational amplifier V U5 via the network resistor I RN1, and the other voltage passes through the inverting input terminal of the operational amplifier V U5. The operational amplifier V U5 obtains a difference value between the non-inverting voltage and the inverting voltage. An inverting voltage is made to the operational amplifier VI U6, and is summed to an output voltage of the DAC U1.

2. The voltage of the operational amplifier II U2 is output to Vref of the DAC U1 as a reference voltage. The DAC U1 receives a signal through a program, which receives calibration data as an output that is transmitted to the operational amplifier III U3. The output is compensated to the voltage output end through the operational amplifier III U3. The program compares the difference value tested and obtained by the differential operational amplifier with the high-accuracy detector, and the DAC U1 is used to compensate the difference value to the output end of the differential operational amplifier.

3. U4 plays a protection role

A high-end voltage differential sampling and calibration method includes the following steps:
step 1, the power input terminal I IN1 provides an inverting voltage source, and the power input terminal II IN2 provides a non-inverting voltage source;
step 2, the sampling resistor RF is used as a point for sampling a voltage at two ends and acquiring a voltage value; and
step 3, when an inverting voltage needs to be acquired, the inverting voltage flows through the network resistor I RN1 to the inverting input terminal of the operational amplifier V U5, is output to the resistor IX R9, the network resistor II RN2, the operational amplifier VI U6, and the output end II Force in sequence through the output end of the operational amplifier V U5, and flows out of an output port through the output end II Force; at this time, a voltage at the output port of the output end II Force is not within a test range, tested data of the accuracy detector and tested data of the calibration controller need to be compared to obtain a difference value, and then the obtained difference value is transmitted to the memory; the calibration controller compensates the non-inverting and inverting voltages stored in the memory according to the difference value obtained by the accuracy detector to obtain a non-inverting voltage for compensation and an inverting voltage for compensation; the DAC U1 performs signal conversion on the non-inverting voltage for compensation and the inverting voltage for compensation, and compensates a converted signal to an output voltage of the differential operational amplifier, so that the voltage value output by the conversion of the DAC U1 is compensated (added to or subtracted from) the voltage at the output end of the operational amplifier VI U6 for summation, so as to achieve an ideal output voltage value;
step 3, when a non-inverting voltage needs to be acquired, the voltage reaches the output end via the resistor IV R4, the operational amplifier IV U4, the resistor V R5, the resistor VI R6, the resistor VII R7, the network resistor I RN1, the operational amplifier V U5, the resistor IX R9, and the operational amplifier VI U6 in sequence; and after being calibrated, the voltage is converted by using the DAC U1 to output a data compensation value for summation, thereby obtaining a stable voltage.

The above describes only the preferred embodiments of the present disclosure. It should be noted that those of ordinary skill in the art can further make several improvements and retouches without departing from the principles of the present disclosure. These improvements and retouches shall all fall within the protection scope of the present disclosure.

What is claimed is:

1. A high-end voltage differential sampling and calibration system, comprising an accuracy detector, a calibration controller, a differential operational amplifier, a comparator, a memory, and a digital to analog converter (DAC),
wherein the differential operational amplifier is configured to: acquire a non-inverting voltage and an inverting voltage of a to-be-tested device, and output a difference value, calculated by the differential operational amplifier, between the non-inverting voltage and the inverting voltage to the comparator;
the comparator is configured to: acquire the difference value, output by the differential operational amplifier, between the non-inverting voltage and the inverting voltage to the comparator, and output the acquired difference value between the non-inverting voltage and the inverting voltage to the memory;
the accuracy detector is configured to: detect the difference value between the non-inverting voltage and the inverting voltage of the to-be-tested device acquired by the differential operational amplifier, and send the detected difference value to the calibration controller;
the calibration controller compensates, according to the difference value sent by the accuracy detector, the non-inverting voltage and the inverting voltage which are stored in the memory, compares the difference value sent by the accuracy detector with an ideal voltage, and takes a difference value between the difference value and the ideal voltage as a non-inverting voltage for compensation and an inverting voltage for compensation;
the DAC is configured to: perform signal conversion on the non-inverting voltage for compensation and the inverting voltage for compensation which are obtained by the calibration controller, and compensate a converted signal to an output voltage of the differential operational amplifier;
the sampling and calibration system comprises an operational amplifier II U2, a resistor I R1, a resistor II R2, a DAC U1, a capacitor II C2, an operational amplifier III U3, a resistor X R10, a network resistor II RN2, an operational amplifier VI U6, a capacitor III C3, an operational amplifier V U5, a network resistor I RN1, a resistor IX R9, a resistor VI R6, a resistor VII R7, a resistor V R5, a resistor IV R4, and an operational amplifier IV U4, wherein:
an inverting input terminal of the operational amplifier II U2 is connected to a power input terminal I IN1 through the resistor II R2; a non-inverting input terminal of the operational amplifier II U2 is grounded; an output end of the operational amplifier II U2 is connected to a reference signal input terminal of the DAC U1; one end of the resistor I R1 is connected to the inverting input terminal of the operational amplifier II U2, and the other end is connected to an output end of the operational amplifier II U2;
an inverting input terminal of the operational amplifier III U3 is connected to a signal output terminal I of the DAC U1; a non-inverting input terminal of the operational amplifier III U3 is connected to a signal output terminal II of the DAC U1; the non-inverting input terminal of the operational amplifier III U3 is grounded; an output end of the operational amplifier III U3 is connected to a feedback signal terminal Rfb of the DAC U1; one end of the capacitor II C2 is connected to the feedback signal terminal Rfb of the DAC U1, and the other end is connected to the signal output terminal of the DAC U1;
an inverting input terminal of the operational amplifier VI U6 is connected to the output end of the operational amplifier III U3 through the resistor X R10; a non-inverting input terminal of the operational amplifier VI U6 is grounded; an output end of the operational amplifier VI U6 is connected to an output end II Force; one end of the capacitor III C3 is connected to the inverting input terminal of the operational amplifier VI U6, and the other end is connected to the output end of the operational amplifier VI U6; a test point II TP2 is arranged on a connecting line between the output end II Force and the output end of the operational amplifier VI U6; the test point II TP2 is connected with a connecting line of the output end of the operational amplifier VI U6 through the network resistor II RN2;
an inverting input terminal of the operational amplifier V U5 is connected to a power input terminal I IN1 through the network resistor I RN1; a non-inverting input terminal of the operational amplifier V U5 is grounded; an output end of the operational amplifier V U5 is connected to the inverting input terminal of the operational amplifier VI U6 through the resistor LY R9 and the network resistor II RN2; the inverting input terminal of the operational amplifier V U5 is connected to the output end of the operational amplifier V U5 through the network resistor I RN1;
an inverting input terminal of the operational amplifier IV U4 is connected to a test point I TP1; a non-inverting input terminal of the operational amplifier IV U4 is connected to a power input terminal II IN2 through the resistor IV R4; an output end of the operational amplifier IV U4 is connected to the test point I TP1 through the resistor V R5; the test point I TP1 is connected to the non-inverting input terminal of the operational amplifier V U5 through the network VI R6 and the network resistor I RN1; and the resistor VII R7 is connected in parallel at both ends of the resistor VI R6; and
a sampling resistor RF is connected between the power input terminal II IN2 and the power input terminal I IN1.

2. A calibration method based on the high-end voltage differential sampling and calibration system according to claim 1, comprising the following steps:
step 1, the power input terminal I IN1 provides an inverting voltage source, and the power input terminal II IN2 provides a non-inverting voltage source;
step 2, the sampling resistor RF is used as a point for sampling a voltage at two ends and acquiring a voltage value; and
step 3, when an inverting voltage needs to be acquired, the inverting voltage flows through the network resistor I RN1 to the inverting input terminal of the operational amplifier V U5, is output to the resistor IX R9, the network resistor II RN2, the operational amplifier VI U6, and the output end II Force in sequence through the output end of the operational amplifier V U5, and flows out of an output port through the output end II Force; if a voltage at the output port of the output end II Force is not within a test range, tested data of the accuracy detector and tested data of the calibration controller are compared to obtain a difference value; the obtained difference value is transmitted to the memory; the calibration controller compensates the non-inverting and inverting voltages stored in the memory according to the difference value obtained by the accuracy detector to obtain a non-inverting voltage for compensation and an inverting voltage for compensation; and the DAC U1 performs signal conversion on the non-inverting voltage for compensation and the inverting voltage for compensation, and compensates a converted signal to an output voltage of the differential operational amplifier.
